(19) United States
(12) Patent Application Publication
(10) Pub. No.: US 2023/0008951 A1
(43) Pub. Date: Jan. 12, 2023

(54) APPARATUS AND METHOD FOR TERAHERTZ-BASED READING OF DATA RECORDED INTO RUDERMAN-KITTEL-KASUYA-YOSIDA (RKKY)-BASED MAGNETIC MEMORY WITHOUT DISSIPATION OF ENERGY IN THE MEDIUM

(71) Applicant: Magtera, Inc., Walnut Creek, CA (US)

(72) Inventor: Boris G Tankhilevich, Walnut Creek, CA (US)

(21) Appl. No.: 17/853,059

(22) Filed: Jun. 29, 2022

Related U.S. Application Data
(63) Continuation-in-part of application No. 17/002,431, filed on Aug. 25, 2020, now Pat. No. 11,411,368.
Application No. 17/002,431 is a continuation-in-part of application No. 16/704,090, filed on Dec. 5, 2019, now Pat. No. 10,790,635.
Application No. 16/704,090 is a continuation-in-part of application No. 16/245,224, filed on Jan. 10, 2019, now Pat. No. 10,892,602.
Application No. 16/245,224 is a continuation-in-part of application No. 16/245,247, filed on Jan. 10, 2019, now Pat. No. 10,804,671.

(51) Int. Cl. G11C 13/06; H01S 1/02; G11C 11/16; H01F 10/32

(52) U.S. Cl. CPC G11C 13/06; H01S 1/02; G11C 11/161; G11C 11/1673; H01F 10/3268; H01S 2302/02

(57) ABSTRACT

The apparatus and the method for terahertz-based reading of data recorded in the Ruderman-Kittel-Kasuya-Yosida (RKKY)-based magnetic memory provided. The apparatus comprises: a Terahertz Magnon Laser configured to generate THz magnons; wherein the Terahertz Magnon Laser further comprises a Magnon Gain Medium (MGM) configured to support generation of non-equilibrium Terahertz magnons after the electric current is applied across the Terahertz Magnon Laser. The apparatus further comprises a magnetic reading bridge coupled to the Magnon Gain Medium of the Terahertz Magnon Laser; the magnetic reading bridge also coupled to a Ruderman-Kittel-Kasuya-Yosida (RKKY)-based magnetic memory cell; wherein magnetization of the magnetic reading bridge is induced by the overall magnetization of the RKKY)-based magnetic memory cell, and wherein the overall magnetization of the RKKY)-based magnetic memory cell is dependent on the information bit encoded into the magnetic memory cell, and wherein the encoded bit ‘1’ corresponds to the higher overall magnetization of the memory cell, and wherein the encoded bit ‘0’ corresponds to the lower overall magnetization of the memory cell. The apparatus further comprises a terahertz demodulator configured to demodulate the generated THz reading signal; wherein the higher detected THz frequency corresponds to reading bit ‘1’ encoded into the RKKY-based magnetic memory cell; and wherein the lower detected THz frequency corresponds to reading bit ‘0’ encoded into the RKKY-based magnetic memory cell.

### CROSS REFERENCE TO RELATED APPLICATIONS

This application is a continuation-in-part of, and claims priority of the application Ser. No. 17/002,431 Filed Aug. 25 2020 and titled “Novel Technique of High-Speed Magnetic recording based on Manipulating pinning layer in Magnetic Tunnel Junction-based memory by using Terahertz Magnon Laser”.

This application is a continuation-in-part of, and claims priority to, U.S. Pat. No. 10,790,635 “Technique of high-speed magnetic recording based on manipulating pinning layer in magnetic tunnel junction-based memory by using Terahertz Magnon Laser”; issued on Sep. 29, 2020.

This application is a continuation-in-part of, and claims priority of the U.S. Pat. No. 10,892,602 “Tunable multilayer Terahertz Magnon Generator” issued on Jan. 12, 2021

This application is a continuation-in-part of, and claims priority of the U.S. Pat. No. 10,804,671 “Terahertz Magnon Generator comprising plurality of single Terahertz Magnon Lasers” issued om Oct. 13, 2020.

The U.S. Pat. Nos. 10,790,635; 10,804,671 and 10,892,602 are assigned to Magtera, Inc.

The entireties of the foregoing patent and patent applications listed herein are hereby incorporated by reference.

### TECHNICAL FIELD

The present disclosure relates to the field of magnon lasers employed to generate terahertz radiation.

### BACKGROUND

While recent developments in photonics enable lossless data transfer with speeds exceeding 1 Tb/s, current magnetic data storage cannot keep up with these data-flow rates nor decrease energy dissipations. Consequently, already now data centers are becoming the biggest consumers of electricity world-wide. Antiferromagnets represent a highly promising playground for the quest for the fastest and the least-dissipative mechanism of data storage. However, in thermodynamic equilibrium, the energy of interaction of a magnetic field with the antiferromagnetic Néel vector is zero. Despite the 60-year long search for thermodynamic conjugates to the antiferromagnetic order parameter, efficient means to control antiferromagnetism are still being pursued. It is the main reason that hampers applications of antiferromagnets and further development of antiferromagnetic spintronics, magnonics and data storage.

Although many experimental and theoretical studies make us believe that ultrafast writing of bits in antiferromagnets at THz rates must be possible, such an ultrafast writing has never been demonstrated in antiferromagnetic media and the highest frequency of rewriting of magnetic bits (100 GHz) belongs to ferrimagnets. The landmark of 1 THz remains to be a monumental challenge.

The assigned to Magtera, Inc., the U.S. Pat. No. 10,790,635 met this challenge by disclosing the technique of using a tunable terahertz writing signal generated by Terahertz Magnon Laser (U.S. Pat. Nos. 10,892,602, 10,804,671) to record the information in a memory cell including an Ruderman-Kittel-Kasuya-Yosida (RKKY) pinning layer (spacer) without dissipation of energy in the medium itself.

More specifically, the described method was based on manipulating the effective thickness of RKKY spacer, and the sign of RLKKY interaction accordingly, from ferromagnetic interaction to antiferromagnetic interaction by using tunable terahertz signal without dissipation of energy in magnetic cell itself because the recording is performed without sending electric current via the magnetic cell itself.

### SUMMARY

The present application discloses an apparatus and method for terahertz-based reading of data recorded in RKKY-based magnetic memory without dissipation of energy in the medium because the reading is performed without sending electric current via the magnetic cell itself.

### BRIEF DESCRIPTION OF THE DRAWINGS

The Figures can have the same, or similar, reference signifiers in the form of labels (such as alphanumeric symbols, e.g., reference numerals), and can signify aa similar or equivalent function or use. Further, reference signifiers of the same type can be distinguished by appending to the reference label a dash and a second label that distinguishes among the similar signifiers. If only the first label is used in the Specification, its use applies to any similar component having the same label irrespective of any other reference labels. A brief list of the Figures is below.

FIG. 1 is a detailed diagram of an RKKY based memory cell for the purposes of the present technology.

FIG. 2 depicts .RKKY interaction for the memory cell structure of FIG. 1 for the purposes of the present technology.

FIG. 3 illustrates the terahertz magnon laser 1 for the purposes of the present technology.

FIG. 4 shows the apparatus of the present technology for fast reading of data encrypted into RKKY-based memory cell (of FIG. 1) without energy dissipation in the medium for the purposes of the present technology.

In the Figures, reference signs can be omitted as is consistent with accepted engineering practice; however, a skilled person will understand that the illustrated components are understood in the context of the Figures as a whole, of the accompanying writings about such Figures, and of the embodiments of the claimed inventions.

### DETAILED DESCRIPTION

The Figures and Detailed Description, only to provide knowledge and understanding, signify at/at least one ECIN. To minimize the length of the Detailed Description, while various features, structures or characteristics can be described together in a single embodiment, they also can be used in other embodiments without being written about. Variations of any of these elements, and modules, processes, machines, systems, manufactures, or compositions disclosed by such embodiments and/or examples are easily used in commerce. The Figures and Detailed Description signify, implicitly or explicitly, advantages and improvements of at least one ECIN for use in commerce.

In the Figures and Detailed Description, numerous specific details can be described to enable at least one ECIN. Any embodiment disclosed herein signifies a tangible form of a claimed invention. To not diminish the significance of the embodiments and/or examples in this Detailed Description, some elements that are known to a skilled person can be combined for presentation and for illustration purposes and not be specified in detail. To not diminish the significance of these embodiments and/or examples, some well-known processes, machines, systems, manufactures, or compositions are not written about in detail. However, a skilled person can use these embodiments and/or examples in commerce without these specific details or their equivalents. Thus, the Detailed Description focuses on enabling the inventive elements of any ECIN. Where this Detailed Description refers to some elements in the singular tense, more than one element can be depicted in the Figures and like elements are labeled with like numerals.

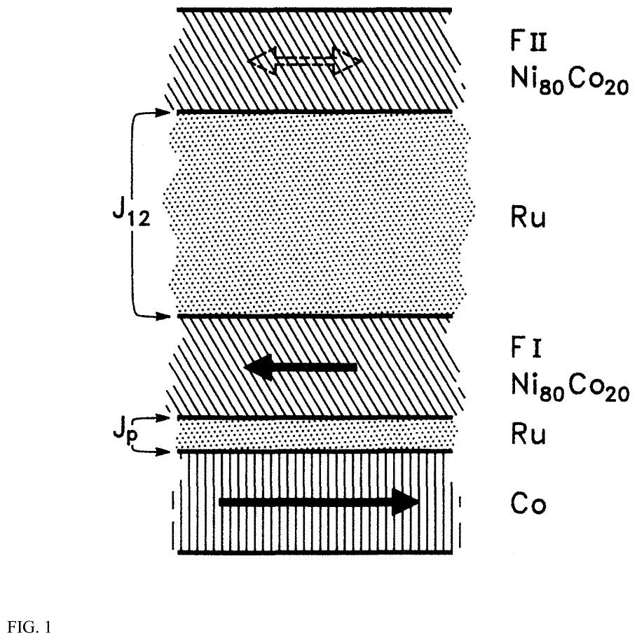

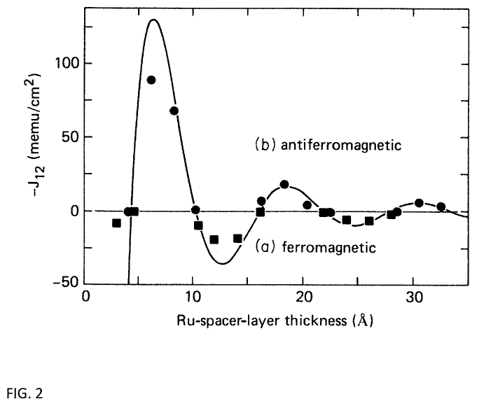

FIG. 1 illustrates the RKKY-based memory cell for the purposes of the present technology. The exchange coupling, J_{1,2} between two Ni₈₀Co₂₀ layers is measured by pinning the moment of one of the Ni₈₀Co₂₀ layers (F I) antiparallel to a Co layer.(S. S. P. Parkin et al., “Spin engineering: Direct determination of the Ruderman-Kittel-Kasuya-Yosida Far-field range function in ruthenium Ru)”. PHYSICAL REVIEW B VOLUME 44, NUMBER 13 1 Oct. 1991). The moment of the Co layer is set equal to the sum of the moments of the two Ni ₈₀Co₂ layers. This structure can be used as a memory cell for the purposes of the present technology. If J_{1,2} between two Ni₈₀Co₂₀ layers, as shown in FIG. 2, is 8 A., the sign of interaction between two Ni₈₀Co₂₀ layers is antiferromagnetic, and the overall magnetization of the magnetic cell comprising the sum of magnetizations of Co, and two Ni₈₀Co₂₀ layers is equal to magnetization of just Co as magnetizations of two Ni₈₀Co₂₀ layers cancel each other, that is bit‘1’ can be encoded in such magnetic memory cell configuration.

If, on the other hand, J_{1,2} between two Ni₈₀Co₂₀ layers, as shown in FIG. 2, is 13 A, the sign of interaction between two Ni₈₀Co₂₀ layers is ferromagnetic, and the overall magnetization of the magnetic cell comprising the sum of magnetization of Co, and two Ni₈₀Co₂₀ layers is equal to zero, that is bit ‘0’ can be encoded in such magnetic memory cell configuration.

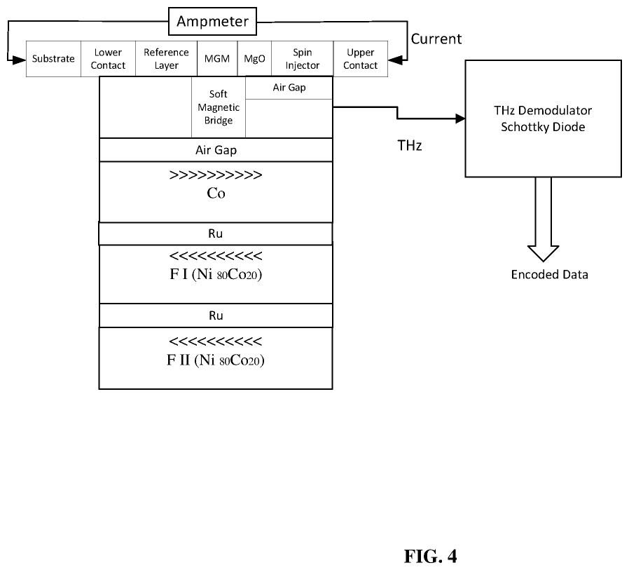

In the embodiment of the present technology, as shown in FIG. 4, the magnetic cell is separated by an air gap from the soft magnetic reading bridge comprising a soft magnetic alloy, like FeCo, that can be easily magnetized (induced) by the overall magnetization of magnetic cell if the air bridge is small enough.

Thus, if the overall magnetization of the magnetic cell comprising the sum of magnetization of Co, and two Ni₈₀Co₂₀ layers (as shown in FIG. 1) is equal to zero, the induced magnetization of magnetic reading bridge is zero, and its initial magnetization of FeCo corresponds to encoded into memory cell of FIG. 1 bit ‘0’.

If, on the other hand, the overall magnetization of the magnetic cell comprising the sum of magnetizations of Co, and two Ni₈₀Co₂₀ layers (of FIG. 1) is equal to magnetization of just Co as magnetizations of two Ni₈₀Co₂₀ layers cancel each other, the overall magnetization of FeCo includes the sum of its initial magnetization and the induced magnetization of Co layer, than the bit encoded into the memory cell of FIG. 1 is ‘1’.

As was disclosed in the U.S. Pat. No. 10,790,635 “Technique of high-speed magnetic recording based on manipulating pinning layer in magnetic tunnel junction-based memory by using Terahertz Magnon Laser”, the information can be recorded into RKKY-based memory cell by using the modulated terahertz radiation.

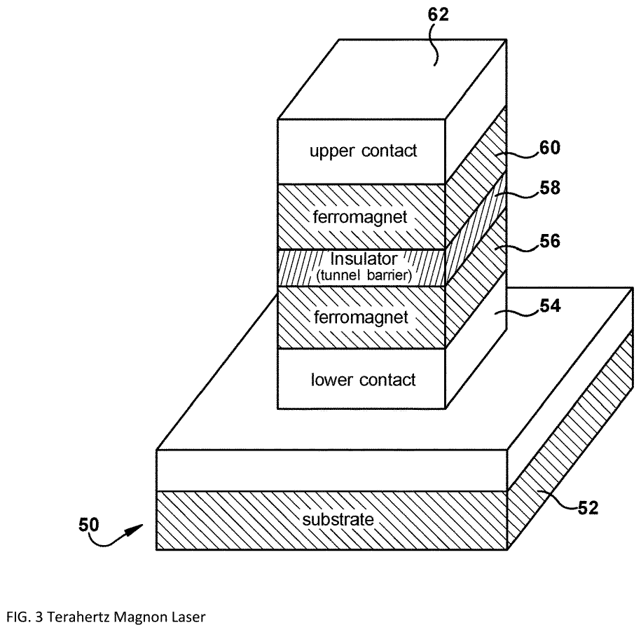

In the embodiment of the present technology, FIG. 4 includes the Terahertz Mangion laser (shown in more details in FIG. 3) coupled to the soft magnetic reading bridge.

In the embodiment of the present technology, the high frequency non-equilibrium THz magnons generated in the Magnon Gain Medium (MGM) of Terahertz Mangion Laser (for more details, please, see the U.S. Pat. Nos. 10,804,671 and 10,892,602 incorporated by reference herein in their entireties) are propagating from MGM into coupled to MGM the soft magnetic reading bridge.

If Magnon Gain Medium (MGM) of Terahertz Mangion Laser is selected from the group consisting of half- metallic ferromagnetic oxide Sr₂FeMoO₆, or Heusler alloy Co₂MnGe, or Heusler alloy Co₂MnSi (CMS), or Heusler alloy Co₂FeSi (CFS), or Heusler alloy Co₂FeAl_{0.5}Si_{0.5} (CFAS), and if the soft magnetic reading bridge is selected from the group of Fe-based soft ferromagnetic alloys with high Curie temperature (like FeCo), the high frequency non-equilibrium THz magnons generated in the Magnon Gain Medium (MGM) of Terahertz Mangion Laser can easily propagate into the soft magnetic reading bridge of FeCo because the magnon stiffness of magnons generated in MGM and propagating into the soft magnetic reading bridge are almost the same.

According to U.S. Pat. No. 7,440,178 “Tunable generation of terahertz radiation”) (U.S. Pat. No. 7,440,178 is assigned to Magtera, Inc. and is incorporated by reference herein in its entirety) the energy of the magnons generated in MGM and propagating into the soft magnetic reading bridge will increase due to magnetization of the soft reading bridge at the rate of 0.056 THz/Tesla.

Thus, when the reading bride is reading bit ‘1’ from the magnetic cell of FIG. 1, its induced magnetization will be higher than in the case of magnetic reading bridge reading the magnetic cell with encoded bit ‘0; as was explained above.

Accordingly, the non-equilibrium THz magnons propagating in soft magnetic reading bridge when the bit ‘1’ is read, will have higher energy (and frequency) than in the case of magnetic cell encoded with bit ‘0’.

As was disclosed in U.S. Pat. Nos. 10,804,671 and 10,892,602, each pair of THz magnons merge into a single THz photon, therefore when the bit ‘1’ is read the THz photons emanating from the magnetic reading bridge (the reading signal) will have higher frequency than in the case of reading bit ‘0’. These reading operations do not involve any energy dissipation inside magnetic medium itself (magnetic cells) as no electric current is sent via the magnetic cell to enable the reading operations and the air gap between the magnetic reading bridge and magnetic cells provides additional means for preventing any additional energy dissipation (for example, mechanical energy of friction) inside magnetic medium.

In the embodiment of the present technology, to differentiate between bits ‘1’ and ‘0’ encoded into magnetic cell of FIG. 1, it is sufficient to detect the frequency of the THz reading signal.

In the embodiment of the present technology, to detect the frequency of the THz reading signal we can use the demodulation block (of FIG. 4) including the Schottky diode.

For example, the paper by Mario Schiselski et al. and published in 2016 IEEE. MTT-S International Microwave Symposium (IMS) discloses “A planar Schottky diode based integrated THz detector for fast electron pulse diagnostics”.

In the embodiment of the present technology, in operation, the method of the present technology using the apparatus for terahertz-based reading of data recorded in RKKY-based magnetic memory without dissipation of energy in the medium comprises the following steps: (A) generating the THz magnons by using Terahertz Magnon laser; (B) configuring the apparatus of the present technology so that the generated THz magnons propagate into magnetic reading bridge coupled to the Magnon Gain Medium of the Terahertz Magnon Laser; and (C) using the THz demodulator including the Schottky diode configured to demodulate the generated THz reading signal; wherein the higher detected THz frequency corresponds to reading bit ‘1’ encoded into the RKKY-based magnetic memory cell; and wherein the lower detected THz frequency corresponds to reading bit ‘0’ encoded into the RKKY-based magnetic memory cell.

The above discussion has set forth the operation of various exemplary systems and devices, as well as various embodiments pertaining to exemplary methods of operating such systems and devices. In various embodiments, one or more steps of a method of implementation (calculating the optimum voltage bias, for example) are carried out by a processor under the control of computer-readable and computer-executable instructions. Thus, in some embodiments, these methods are implemented via a computer.

In an embodiment, the computer-readable and computer-executable instructions may reside on computer useable/readable media.

Therefore, one or more operations of various embodiments may be controlled or implemented using computer-executable instructions, such as program modules, being executed by a computer. Generally, program modules include routines, programs, objects, components, data structures, etc., that perform particular tasks or implement particular abstract data types. In addition, the present technology may also be practiced in distributed computing environments where tasks are performed by remote processing devices that are linked through a communications network. In a distributed computing environment, program modules may be located in both local and remote computer-storage media including memory-storage devices.

Although specific steps of exemplary methods of implementation are disclosed herein, these steps are examples of steps that may be performed in accordance with various exemplary embodiments. That is, embodiments disclosed herein are well suited to performing various other steps or variations of the steps recited. Moreover, the steps disclosed herein may be performed in an order different than presented, and not all of the steps are necessarily performed in a particular embodiment.

Although various electronic and software-based systems are discussed herein, these systems are merely examples of environments that might be utilized and are not intended to suggest any limitation as to the scope of use or functionality of the present technology. Neither should such systems be interpreted as having any dependency or relation to any one or combination of components or functions illustrated in the disclosed examples.

Although the subject matter has been described in a language specific to structural features and/or methodological acts, the subject matter defined in the appended claims is not necessarily limited to the specific features or acts described above. Rather, the specific features and acts described above are disclosed as exemplary forms of implementing the claims.

What is claimed is:

1. The apparatus for terahertz-based reading of data recorded in the Ruderman-Kittel-Kasuya-Yosida (RKKY)-based magnetic memory; said apparatus comprises:
(A) a Terahertz Magnon Laser configured to generate THz magnons; said Terahertz Magnon Laser comprising a Magnon Gain Medium (MGM) configured to support generation of non-equilibrium Terahertz magnons after the electric current is applied across the Terahertz Magnon Laser;
(B) a magnetic reading bridge coupled to said Magnon Gain Medium of said Terahertz Magnon Laser; said magnetic reading bridge also coupled to a Ruderman-Kittel-Kasuya-Yosida (RKKY)-based magnetic memory cell; wherein magnetization of said magnetic reading bridge is induced by the overall magnetization of said RKKY)-based magnetic memory cell, and wherein the overall magnetization of said RKKY)-based magnetic memory cell is dependent on the information bit encoded into said magnetic memory cell, and wherein said encoded bit ‘1’ corresponds to the higher overall magnetization of said memory cell, and wherein said encoded bit ‘0’ corresponds to the lower overall magnetization of said memory cell;
and
(C) a terahertz demodulator configured to demodulate the generated THz reading signal; wherein the higher detected THz frequency corresponds to reading bit ‘1’ encoded into said RKKY-based magnetic memory cell; and wherein the lower detected THz frequency corresponds to reading bit ‘0’ encoded into said RKKY-based magnetic memory cell.

2. The apparatus of claim 1 further comprising:
said Ruderman-Kittel-Kasuya-Yosida (RKKY)-based magnetic memory cell further comprising:
a reference layer;
a first RKKY-based spacer coupled to said reference;
an anti-parallel layer coupled to said reference layer by an antiferromagnetic RKKY-interaction enabled by said first RKKY-based spacer; wherein magnetization of said anti-parallel layer is antiparallel to magnetization of said reference layer;
a second RKKY-based spacer coupled to said anti-parallel layer; and
a free layer coupled to said second RKKY-based spacer; wherein the magnetization of said free layer is determined by the sign of RKKY interaction selected by manipulating the thickness of said second RKKY-based layer.

3. The apparatus of claim 2; wherein said first RKKY-based spacer is selected from a group of materials consisting of:
Ruthenium (Ru); and Copper (Cu).

4. The apparatus of claim 2; wherein said second RKKY-based spacer is selected from a group of materials consisting of:
Ruthenium (Ru); and Copper (Cu).

5. The apparatus of claim 2; wherein said reference layer further comprises:
Cobalt Co.

6. The apparatus of claim 2; wherein said anti-parallel layer further comprises:
Cobalt alloy Ni₈₀Co₂₀.

7. The apparatus of claim 2; wherein said free layer further comprises:
Cobalt alloy Ni₈₀Co₂₀.

8. The apparatus of claim 1; wherein Magnon Gain Medium (MGM) comprises a material selected from the group consisting of:
a Heusler alloy Co₂MnGe; a Heusler alloy Co₂MnSi (CMS); a Heusler alloy Co₂FeSi (CFS); and Heusler alloy Co₂FeAl_{0.5}Si_{0.5} (CFAS).

9. The apparatus of claim 1; wherein said magnetic reading bridge comprises a material selected from the group consisting of:
Fe-based soft ferromagnetic alloys with high Curie temperature; and FeCo.

10. The apparatus of claim 1; wherein said magnetic reading bridge comprises a material having a magnon stiffness substantially the same as magnon stiffness of magnons generated in said MGM.

11. The apparatus of claim 1; wherein said THz demodulator further comprises;
A Schottky diode configured to demodulate the generated THz reading signal.

12. A method for terahertz-based reading of data recorded in RKKY-based magnetic memory comprising:
(A) generating the THz magnons by using a Terahertz Magnon laser further comprising a Magnon Gain Medium;
(B) providing a magnetic reading bridge coupled to said Magnon Gain Medium; wherein the generated THz magnons are configured to propagate into said magnetic reading bridge; said magnetic reading bridge magnetically coupled to an RKKY-based memory cell;
and
(C) using a THz demodulator to demodulate the generated THz reading signal; wherein the higher detected THz frequency corresponds to reading bit ‘1’ encoded into said RKKY-based magnetic memory cell; and wherein the lower detected THz frequency corresponds to reading bit ‘0’ encoded into said RKKY-based magnetic memory cell.

13. The method of claim 12, wherein said step (A) further comprises:
(A1) selecting said Magnon Gain Medium (MGM) from the group consisting of:
a Heusler alloy Co₂MnGe; a Heusler alloy Co₂MnSi (CMS); a Heusler alloy Co₂FeSi (CFS); and Heusler alloy Co₂FeAl_{0.5}Si_{0.5}(CFAS).

14. The method of claim 12, wherein said step (B) further comprises:
(B1) selecting said magnetic reading from the group consisting of:
Fe-based soft ferromagnetic alloys with high Curie temperature; and FeCo.

15. The method of claim 12, wherein said step (B) further comprises:
(B2) providing said RKKY-based memory cell having info encoded into said memory cell.

16. The method of claim 12, wherein said step (B) further comprises:
(B3) providing said RKKY-based memory cell having info encoded into said memory cell further comprising:
a reference layer;
a first RKKY-based spacer coupled to said reference;
an anti-parallel layer coupled to said reference layer by an antiferromagnetic RKKY-interaction enabled by said first RKKY-based spacer; wherein magnetization of said anti-parallel layer is antiparallel to magnetization of said reference layer;
a second RKKY-based spacer coupled to said anti-parallel layer;
and
a free layer coupled to said second RKKY-based spacer; wherein the magnetization of said free layer is determined by the sign of RKKY interaction selected by manipulating the thickness of said second RKKY-based layer.

17. The method of claim 12, wherein said step (B) further comprises
(B4) providing said RKKY-based memory cell having info encoded into said memory cell by using modulated terahertz radiation.

18. The method of claim 12, wherein said step (B) further comprises
(B5) using said RKKY-based memory cell having info encoded into said memory cell to induce the overall magnetization of said memory cell into said magnetic reading bridge.

19. The method of claim 18, wherein said step (B5) further comprises:
(B5, 1) using said induced magnetization of said magnetic reading bridge to modulate the frequency of said generated terahertz reading signal

20. The method of claim 12, wherein said step (C) further comprises:
(C1) using a Schottky diode to enable said THz demodulator to extract the information encoded into said RKKY-based memory cell by demodulating said terahertz reading signal.
